(19) United States
(12) Patent Application Publication
(10) Pub. No.: US 2023/0255047 A1
(43) Pub. Date: Aug. 10, 2023

(54) ENHANCED PURCELL EFFECT USING RED-SHIFTED SURFACE PLASMON MODES AND HIGH INDEX MATERIAL IN ORGANIC LIGHT EMITTING DEVICES

(71) Applicant: The Regents of the University of Michigan, Ann Arbor, MI (US)

(72) Inventors: Haonan Zhao, Ann Arbor, MI (US); Stephen R. FORREST, Ann Arbor, MI (US)

(21) Appl. No.: 18/157,308

(22) Filed: Jan. 20, 2023

Related U.S. Application Data
(60) Provisional application No. 63/301,519, filed on Jan. 21, 2022.

(51) Int. Cl. H10K 50/16; H10K 50/816; H10K 50/82

(52) U.S. Cl. CPC H10K 50/16; H10K 50/816; H10K 50/82; H10K 2102/20

(57) ABSTRACT

An OLED comprises a first electrode, an emissive layer positioned over the first electrode, a charge transport layer positioned over the emissive layer, and a second electrode positioned over the charge transport layer, wherein the charge transport layer is in direct contact with the second electrode, and wherein the charge transport layer has an index of refraction of at least 1.7. An OLED comprises a cavity formed between first and second metal electrodes, an organic light emitting element positioned within the cavity, and an efficiency enhancement layer positioned between the organic light emitting element and the second silver electrode, the efficiency enhancement layer having a refractive index of at least 1.7.

### CROSS-REFERENCE TO RELATED APPLICATIONS

This application claims priority to U.S. provisional application No. 63/301,519 filed on Jan. 21, 2022, incorporated herein by reference in its entirety.

### STATEMENT REGARDING FEDERALLY SPONSORED RESEARCH OR DEVELOPMENT

This invention was made with government support under FA9550-18-1-0162 awarded by the U.S. Air Force Office of Scientific Research. The government has certain rights in the invention.

### BACKGROUND OF THE INVENTION

Organic light emitting devices (OLEDs), especially phosphorescent OLEDs, suffer from triplet-triplet annihilation (TTA) and triplet-polaron annihilation (TPA) due to the long lifetime of triplet excitons. Therefore, increasing the radiative decay rate of a triplet exciton by introducing a stronger Purcell effect, can reduce triplet exciton density in the emission layer and achieve a longer device operational lifetime. Some previous cavity designs utilize multiple silver surfaces in the near-field region to maximize the radiative coupling between the exciton energy and silver surface plasmon polariton (SPP) modes. Simulation results show a Purcell factor of around 5 is achieved, which means the radiative lifetime can reach at minimum one-fifth of that in vacuum or in the infinite host material environment. However, these multilayers bring new difficulties to the fabrication process. Thus there is a need in the art for improved devices, systems and methods for enhancing exciton decay rate in OLEDs.

### SUMMARY OF THE INVENTION

Some embodiments of the invention disclosed herein are set forth below, and any combination of these embodiments (or portions thereof) may be made to define another embodiment.

In one aspect, an OLED comprises a first electrode, an emissive layer positioned over the first electrode, a charge transport layer positioned over the emissive layer, and a second electrode positioned over the charge transport layer, wherein the charge transport layer is in direct contact with the second electrode, and wherein the charge transport layer has an index of refraction of at least 1.7.

In one embodiment, the charge transport layer comprises a material selected from Alq₃, BPyTP₂, or ZnS. In one embodiment, the charge transport layer has a thickness of between 10 nm and 30 nm. In one embodiment, the charge transport layer has a thickness of about 15 nm. In one embodiment, the second electrode is a cathode and the charge transport layer is an electron transport layer. In one embodiment, the first electrode and the second electrode both comprise silver. In one embodiment, the first electrode has a thickness of about 30 nm, and the second electrode has a thickness of about 100 nm. In one embodiment, the OLED further comprises a first Indium Tin oxide (ITO) layer between the first electrode and the emissive layer. In one embodiment, the first ITO layer has a thickness of about 15 nm. In one embodiment, the OLED further comprises a second ITO layer below the first electrode. In one embodiment, the charge transport layer has a refractive index of at least 1.9. In one embodiment, the charge transport layer has a refractive index of at least 2.0.

In another aspect, an OLED comprises a cavity formed between first and second metal electrodes, an organic light emitting element positioned within the cavity, and an efficiency enhancement layer positioned between the organic light emitting element and the second silver electrode, the efficiency enhancement layer having a refractive index of at least 1.7.

In one embodiment, the efficiency enhancement layer has a refractive index of at least 1.9. In one embodiment, the efficiency enhancement layer has a refractive index of at least 2.0. In one embodiment, the efficiency enhancement layer comprises an electron transporting material. In one embodiment, the cavity has a Purcell factor of at least 5. In one embodiment, the OLED further comprises an ITO layer positioned within the cavity. In one embodiment, wherein the ITO layer is positioned between the first metal electrode and the organic light emitting element. In one embodiment, the organic light emitting element is a white organic light emitting element.

### BRIEF DESCRIPTION OF THE DRAWINGS

The foregoing purposes and features, as well as other purposes and features, will become apparent with reference to the description and accompanying figures below, which are included to provide an understanding of the invention and constitute a part of the specification, in which like numerals represent like elements, and in which:

FIG. 1 is a block diagram depicting an exemplary OLED in accordance with some embodiments.

FIG. 2 is a block diagram depicting an exemplary inverted organic light emitting device that does not have a separate electron transport layer in accordance with some embodiments.

FIGS. 3A-3B depict the structure of a previous cavity OLED design and a simulation of Purcell factor and outcoupling efficiency at wavelength of 466 nm, respectively, in accordance with some embodiments.

FIG. 4 is a plot showing the dielectric functions (real part) of three materials (Alq₃, BPyTP₂, and ZnS) in accordance with some embodiments.

FIG. 5 depicts an exemplary device structure for a cavity OLED with different ETL layers in accordance with some embodiments.

FIGS. 6A-6D are plots showing modal simulation of devices D1, D2, D3 of FIG. 5, and AIA-IAI as control, respectively, in accordance with some embodiments. The contour plot describes how the total optical power of an exciton is dissipated for each wavelength and wavenumber along the surface.

FIGS. 7A-7D are plots showing simulated figure of merit, Purcell factor and outcoupling efficiency of devices D1, D2, D3 of FIG. 5, and AIA-IAI as control, respectively, in accordance with some embodiments.

### DETAILED DESCRIPTION OF THE INVENTION

It is to be understood that the figures and descriptions of the present invention have been simplified to illustrate elements that are relevant for a clearer comprehension of the present invention, while eliminating, for the purpose of clarity, many other elements found in systems, devices and methods for enhancing exciton decay rate in (OLEDs. Those of ordinary skill in the art may recognize that other elements and/or steps are desirable and/or required in implementing the present invention. However, because such elements and steps are well known in the art, and because they do not facilitate a better understanding of the present invention, a discussion of such elements and steps is not provided herein. The disclosure herein is directed to all such variations and modifications to such elements and methods known to those skilled in the art.

Unless defined otherwise, all technical and scientific terms used herein have the same meaning as commonly understood by one of ordinary skill in the art to which this invention belongs. Although any methods and materials similar or equivalent to those described herein can be used in the practice or testing of the present invention, exemplary methods and materials are described.

As used herein, each of the following terms has the meaning associated with it in this section.

The articles “a” and “an” are used herein to refer to one or to more than one (i.e., to at least one) of the grammatical object of the article. By way of example, “an element” means one element or more than one element.

“About” as used herein when referring to a measurable value such as an amount, a temporal duration, and the like, is meant to encompass variations of ±20%, ±10%, ±5%, ±1%, and ±0.1% from the specified value, as such variations are appropriate.

Ranges: throughout this disclosure, various aspects of the invention can be presented in a range format. It should be understood that the description in range format is merely for convenience and brevity and should not be construed as an inflexible limitation on the scope of the invention. Where appropriate, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 2.7, 3, 4, 5, 5.3, and 6. This applies regardless of the breadth of the range.

Referring now in detail to the drawings, in which like reference numerals indicate like parts or elements throughout the several views, in various embodiments, presented herein are systems, devices and methods for enhancing exciton decay rate in OLEDs. In previous work, Purcell-effect-enhanced cavity OLEDs have been demonstrated by using a pair of silver mirror electrodes with metal-dielectric alternating layers. In this disclosure, a redshift in surface plasmon polariton (SPP) modes induced by high refractive index material is utilized for a higher Purcell factor, achieving a larger radiative decay rate and a longer device operational lifetime. In an embodiment, the high refractive index comes from the anomalous dispersion brought by the coupling between the SPP and the resonant exciton of the charge transport layer (i.e., plasmon exciton polariton). In some embodiments, a strong coupling is formed between the SPP and the plasmon exciton polarity. In alternative embodiment, a weak coupling is formed between the SPP and the plasmon exciton polarity. This provides the degrees of freedom for balancing plasmon coupling to the outcoupling.

Generally, an OLED comprises at least one organic layer disposed between and electrically connected to an anode and a cathode. When a current is applied, the anode injects holes and the cathode injects electrons into the organic layer(s). The injected holes and electrons each migrate toward the oppositely charged electrode. When an electron and hole localize on the same molecule, an “exciton,” which is a localized electron-hole pair having an excited energy state, is formed. Light is emitted when the exciton relaxes via a photoemissive mechanism. In some cases, the exciton may be localized on an excimer or an exciplex. Non-radiative mechanisms, such as thermal relaxation, may also occur, but are generally considered undesirable.

The initial OLEDs used emissive molecules that emitted light from their singlet states (“fluorescence”) as disclosed, for example, in U.S. Pat. No. 4,769,292, which is incorporated by reference in its entirety. Fluorescent emission generally occurs in a time frame of less than 10 nanoseconds.

OLEDs having emissive materials that emit light from triplet states (“phosphorescence”) have been demonstrated. Baldo et al., “Highly Efficient Phosphorescent Emission from Organic Electroluminescent Devices,” Nature, vol. 395, 151-154, 1998; (“Baldo-I”) and Baldo et al., “Very high-efficiency green organic light-emitting devices based on electrophosphorescence,” Appl. Phys. Lett., vol. 75, No. 3, 4-6 (1999) (“Baldo-II”), are incorporated by reference in their entireties. Phosphorescence is described in more detail in U.S. Pat. No. 7,279,704 at cols. 5-6, which are incorporated by reference.

As used herein, and as would be understood by one skilled in the art, “HATCN” (referred to interchangeably as HAT-CN) refers to 1,4,5,8,9,11-Hexaazatriphenylenehexacarbonitrile.

“TAPC” refers to 4,4′-Cyclohexylidenebis[N,N-bis(4-methylphenyl)aniline]. “B3PYMPM” refers to 4,6-Bis(3,5-di(pyridin-3-yl)phenyl)-2-methylpyrimidine. “BPyTP₂” refers to 2,7-Bis(2,2′-bipyridin-5-yl)triphenylene. “LiQ” refers to Lithium Quinolate. “ITO” refers to Indium Tin Oxide. “CBP” refers to 4,4′-Bis(N-carbazolyl)-1,1′-biphenyl. “Ir(ppy)2acac” refers to bis[2-(2-pyridinyl-N)phenyl-C](acetylacetonato)iridium(III).

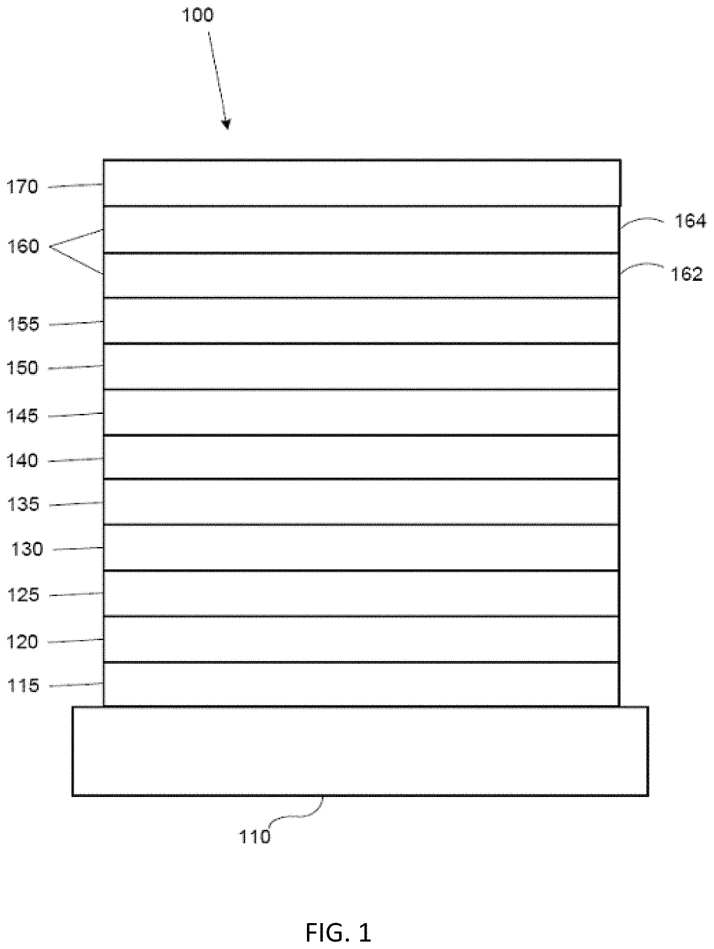

FIG. 1 shows an organic light emitting device 100. The figures are not necessarily drawn to scale. Device 100 may include a substrate 110, an anode 115, a hole injection layer 120, a hole transport layer 125, an electron blocking layer 130, an emissive layer 135, a hole blocking layer 140, an electron transport layer 145, an electron injection layer 150, a protective layer 155, a cathode 160, and a barrier layer 170. Cathode 160 is a compound cathode having a first conductive layer 162 and a second conductive layer 164. Device 100 may be fabricated by depositing the layers described, in order. The properties and functions of these various layers, as well as example materials, are described in more detail in U.S. Pat. No. 7,279,704 at cols. 6-10, which are incorporated by reference.

More examples for each of these layers are available. For example, a flexible and transparent substrate-anode combination is disclosed in U.S. Pat. No. 5,844,363, which is incorporated by reference in its entirety. An example of a p-doped hole transport layer is m-MTDATA doped with F4-TCNQ at a molar ratio of 50:1, as disclosed in U.S. Patent Application Publication No. 2003/0230980, which is incorporated by reference in its entirety. Examples of emissive and host materials are disclosed in U.S. Pat. No. 6,303,238 to Thompson et al., which is incorporated by reference in its entirety. An example of an n-doped electron transport layer is BPhen doped with Li at a molar ratio of 1:1, as disclosed in U.S. Patent Application Publication No. 2003/0230980, which is incorporated by reference in its entirety. U.S. Pat. Nos. 5,703,436 and 5,707,745, which are incorporated by reference in their entireties, disclose examples of cathodes including compound cathodes having a thin layer of metal such as Mg:Ag with an overlying transparent, electrically-conductive, sputter-deposited ITO layer. The theory and use of blocking layers is described in more detail in U.S. Pat. No. 6,097,147 and U.S. Patent Application Publication No. 2003/0230980, which are incorporated by reference in their entireties. Examples of injection layers are provided in U.S. Patent Application Publication No. 2004/0174116, which is incorporated by reference in its entirety. A description of protective layers may be found in U.S. Patent Application Publication No. 2004/0174116, which is incorporated by reference in its entirety.

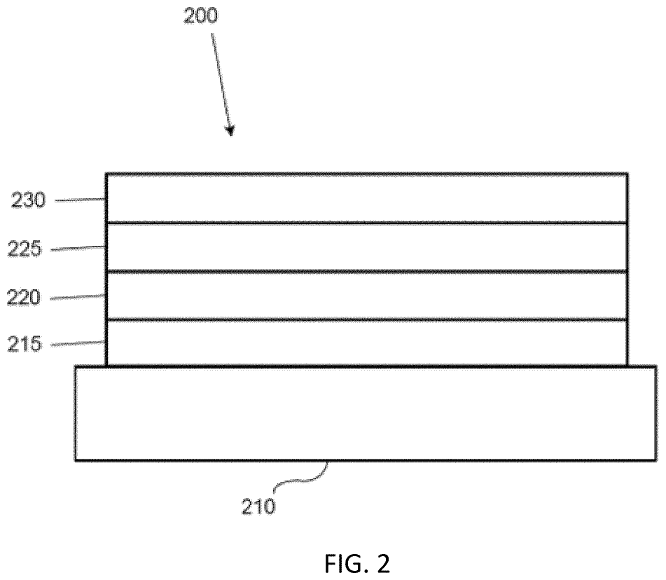

FIG. 2 shows an inverted OLED 200. The device includes a substrate 210, a cathode 215, an emissive layer 220, a hole transport layer 225, and an anode 230. Device 200 may be fabricated by depositing the layers described, in order. Because the most common OLED configuration has a cathode disposed over the anode, and device 200 has cathode 215 disposed under anode 230, device 200 may be referred to as an “inverted” OLED. Materials similar to those described with respect to device 100 may be used in the corresponding layers of device 200. FIG. 2 provides one example of how some layers may be omitted from the structure of device 100.

The simple layered structure illustrated in FIG. 1 and FIG. 2 is provided by way of non-limiting example, and it is understood that embodiments of the disclosure may be used in connection with a wide variety of other structures. The specific materials and structures described are exemplary in nature, and other materials and structures may be used. Functional OLEDs may be achieved by combining the various layers described in different ways, or layers may be omitted entirely, based on design, performance, and cost factors. Other layers not specifically described may also be included. Materials other than those specifically described may be used. Although many of the examples provided herein describe various layers as comprising a single material, it is understood that combinations of materials, such as a mixture of host and dopant, or more generally a mixture, may be used. Also, the layers may have various sublayers. The names given to the various layers herein are not intended to be strictly limiting. For example, in device 200, hole transport layer 225 transports holes and injects holes into emissive layer 220, and may be described as a hole transport layer or a hole injection layer. In one embodiment, an OLED may be described as having an “organic layer” disposed between a cathode and an anode. This organic layer may comprise a single layer, or may further comprise multiple layers of different organic materials as described, for example, with respect to FIGS. 1 and 2.

Although certain embodiments of the disclosure are discussed in relation to one particular device or type of device (for example OLEDs) it is understood that the disclosed improvements to light outcoupling properties of a substrate may be equally applied to other devices, including but not limited to PLEDs, OPVs, charge-coupled devices (CCDs), photosensors, or the like.

Certain embodiments of the disclosure relate to a light emitting device comprising an emissive layer (EML) spaced far from a cathode as described herein. Conventional organic light emitting devices typically place the EML near a metal cathode which incurs plasmon losses due to near field coupling. To avoid exciting these lossy modes it is necessary to space the EML far from the cathode. However, utilizing a thick electron transport layer (ETL) can be problematic due to changes in charge balance and increased resistivity. These problems can be overcome by utilizing a charge generation layer, for example a charge generation layer comprising at least one electron transport layer and at least one hole transport layer, to convert electron into hole current. This allows the use of higher mobility hole transporting materials and maintains the charge balance of the device. In some embodiments, the charge generation layer may be replaced or combined with any other layer capable of conducting electrons.

Structures and materials not specifically described may also be used, such as OLEDs comprised of polymeric materials (PLEDs) such as disclosed in U.S. Pat. No. 5,247,190 to Friend et al., which is incorporated by reference in its entirety. By way of further example, OLEDs having a single organic layer may be used. OLEDs may be stacked, for example as described in U.S. Pat. No. 5,707,745 to Forrest et al, which is incorporated by reference in its entirety. The OLED structure may deviate from the simple layered structure illustrated in FIGS. 1 and 2. For example, the substrate may include an angled reflective surface to improve out-coupling, such as a mesa structure as described in U.S. Pat. No. 6,091,195 to Forrest et al., and/or a pit structure as described in U.S. Pat. No. 5,834,893 to Bulovic et al., which are incorporated by reference in their entireties.

Unless otherwise specified, any of the layers of the various embodiments may be deposited by any suitable method. For the organic layers, preferred methods include thermal evaporation, ink-jet, such as described in U.S. Pat. Nos. 6,013,982 and 6,087,196, which are incorporated by reference in their entireties, organic vapor phase deposition (OVPD), such as described in U.S. Pat. No. 6,337,102 to Forrest et al., which is incorporated by reference in its entirety, and deposition by organic vapor jet printing (OVJP), such as described in U.S. Pat. No. 7,431,968, which is incorporated by reference in its entirety. Other suitable deposition methods include spin coating and other solution based processes. Solution based processes are preferably carried out in nitrogen or an inert atmosphere. For the other layers, preferred methods include thermal evaporation. Preferred patterning methods include deposition through a mask, cold welding such as described in U.S. Pat. Nos. 6,294,398 and 6,468,819, which are incorporated by reference in their entireties, and patterning associated with some of the deposition methods such as ink-jet and OVJD. Other methods may also be used. The materials to be deposited may be modified to make them compatible with a particular deposition method. For example, substituents such as alkyl and aryl groups, branched or unbranched, and preferably containing at least 3 carbons, may be used in small molecules to enhance their ability to undergo solution processing. Substituents having 20 carbons or more may be used, and 3-20 carbons is a preferred range. Materials with asymmetric structures may have better solution processibility than those having symmetric structures, because asymmetric materials may have a lower tendency to recrystallize. Dendrimer substituents may be used to enhance the ability of small molecules to undergo solution processing.

Devices fabricated in accordance with embodiments of the present invention may further optionally comprise a barrier layer. One purpose of the barrier layer is to protect the electrodes and organic layers from damaging exposure to harmful species in the environment including moisture, vapor and/or gases, etc. The barrier layer may be deposited over, under or next to a substrate, an electrode, or over any other parts of a device including an edge. The barrier layer may comprise a single layer, or multiple layers. The barrier layer may be formed by various known chemical vapor deposition techniques and may include compositions having a single phase as well as compositions having multiple phases. Any suitable material or combination of materials may be used for the barrier layer. The barrier layer may incorporate an inorganic or an organic compound or both. The preferred barrier layer comprises a mixture of a polymeric material and a non-polymeric material as described in U.S. Pat. No. 7,968,146, PCT Pat. Application Nos. PCT/US2007/023098 and PCT/US2009/042829, which are herein incorporated by reference in their entireties. To be considered a “mixture”, the aforesaid polymeric and non-polymeric materials comprising the barrier layer should be deposited under the same reaction conditions and/or at the same time. The weight ratio of polymeric to non-polymeric material may be in the range of 95:5 to 5:95. The polymeric material and the non-polymeric material may be created from the same precursor material. In one example, the mixture of a polymeric material and a non-polymeric material consists essentially of polymeric silicon and inorganic silicon.

Devices fabricated in accordance with embodiments of the invention can be incorporated into a wide variety of electronic component modules (or units) that can be incorporated into a variety of electronic products or intermediate components. Examples of such electronic products or intermediate components include display screens, lighting devices such as discrete light source devices or lighting panels, etc. that can be utilized by the end-user product manufacturers. Such electronic component modules can optionally include the driving electronics and/or power source(s). Devices fabricated in accordance with embodiments of the invention can be incorporated into a wide variety of consumer products that have one or more of the electronic component modules (or units) incorporated therein. A consumer product comprising an OLED that includes the compound of the present disclosure in the organic layer in the OLED is disclosed. Such consumer products would include any kind of products that include one or more light source(s) and/or one or more of some type of visual displays. Some examples of such consumer products include flat panel displays, computer monitors, medical monitors, televisions, billboards, lights for interior or exterior illumination and/or signaling, heads-up displays, fully or partially transparent displays, flexible displays, laser printers, telephones, mobile phones, tablets, phablets, personal digital assistants (PDAs), wearable devices, laptop computers, digital cameras, camcorders, viewfinders, micro-displays (displays that are less than 2 inches diagonal), 3-D displays, virtual reality or augmented reality displays, vehicles, video walls comprising multiple displays tiled together, theater or stadium screen, and a sign. Various control mechanisms may be used to control devices fabricated in accordance with the present invention, including passive matrix and active matrix. Many of the devices are intended for use in a temperature range comfortable to humans, such as 18 C to 30 C, and more preferably at room temperature (20-25 C), but could be used outside this temperature range, for example, from −40 C to 80 C.

The materials and structures described herein may have applications in devices other than OLEDs. For example, other optoelectronic devices such as organic solar cells and organic photodetectors may employ the materials and structures. More generally, organic devices, such as organic transistors, may employ the materials and structures.

Devices of the present disclosure may comprise one or more electrodes, some of which may be fully or partially transparent or translucent. In some embodiments, one or more electrodes comprise indium tin oxide (ITO) or other transparent conductive materials. In some embodiments, one or more electrodes may comprise flexible transparent and/or conductive polymers.

Layers may include one or more electrodes, organic emissive layers, electron- or hole-blocking layers, electron- or hole-transport layers, buffer layers, or any other suitable layers known in the art. In some embodiments, one or more of the electrode layers may comprise a transparent flexible material. In some embodiments, both electrodes may comprise a flexible material and one electrode may comprise a transparent flexible material.

An OLED fabricated using devices and techniques disclosed herein may have one or more characteristics selected from the group consisting of being flexible, being rollable, being foldable, being stretchable, and being curved, and may be transparent or semi-transparent. In some embodiments, the OLED further comprises a layer comprising carbon nanotubes.

In some embodiments, an OLED fabricated using devices and techniques disclosed herein further comprises a layer comprising a delayed fluorescent emitter. In some embodiments, the OLED comprises a RGB pixel arrangement or white plus color filter pixel arrangement. In some embodiments, the OLED is a mobile device, a handheld device, or a wearable device. In some embodiments, the OLED is a display panel having less than 10 inch diagonal or 50 square inch area. In some embodiments, the OLED is a display panel having at least 10 inch diagonal or 50 square inch area. In some embodiments, the OLED is a lighting panel.

In some embodiments, the compound can be an emissive dopant. In some embodiments, the compound can produce emissions via phosphorescence, fluorescence, thermally activated delayed fluorescence, i.e., TADF (also referred to as E-type delayed fluorescence), triplet-triplet annihilation, or combinations of these processes.

An OLED fabricated according to techniques and devices disclosed herein can be incorporated into one or more of a consumer product, an electronic component module, and a lighting panel. The organic layer can be an emissive layer and the compound can be an emissive dopant in some embodiments, while the compound can be a non-emissive dopant in other embodiments.

The organic layer can also include a host. In some embodiments, two or more hosts are preferred. In some embodiments, the hosts used maybe a) bipolar, b) electron transporting, c) hole transporting or d) wide band gap materials that play little role in charge transport. In some embodiments, the host can include a metal complex. The host can be an inorganic compound.

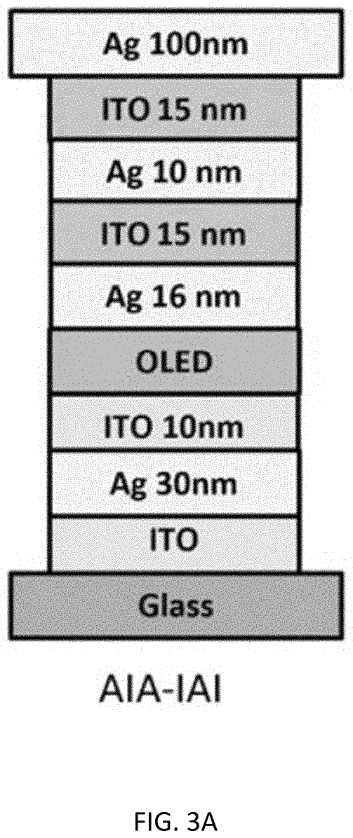

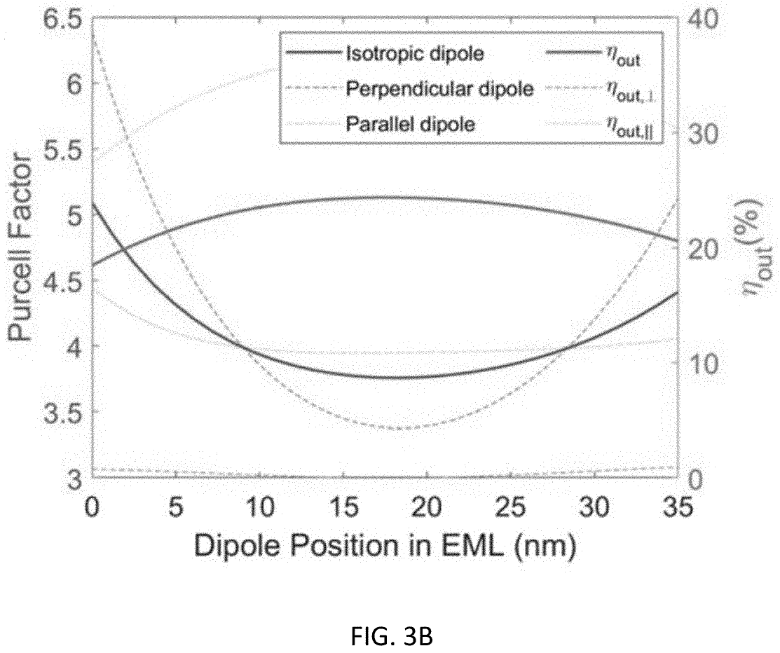

Referring now to FIGS. 3A and 3B, the structure of a previous cavity OLED design and a simulation of Purcell factor and outcoupling efficiency at wavelength of 466 nm are shown, respectively. At an ideal metal/dielectric interface, the SPP dispersion is defined by:

$${k}_{x} = \frac{ω}{c} {( \frac{{ε}_{m} {ε}_{d}}{{ε}_{m} + {ε}_{d}} )}^{1 / 2} \qquad ( 1 )$$

with an asymptotic behavior at kₓ→∞, where ω→ω_{SP}, the surface plasma frequency. The surface plasma frequency is given by the plasma frequency of the metal and the optical constant of the dielectric material:

$${ω}_{SP} = \frac{{ω}_{P}}{\sqrt{1 + {ε}_{d}}} \qquad ( 2 )$$

where by increasing the dielectric function Ed, the SPP dispersion and its density of states are both easily tunable, providing another optical degree of freedom for optoelectronic devices.

The fabrication process by which the device of FIG. 3A is produced can be simplified by changing the dielectric material near the silver (Ag) surface to material with a higher refractive index, one can use a redshifted SPP coupling for a better enhanced Purcell effect. Furthermore, thin Ag or other metal mirrors can be utilized as one or both electrodes for a phosphorescent OLED to enhance cavity effects. In some embodiments, the electron transport layer (ETL) is replaced with a high-n material, for the purpose of both providing a red-shifted dispersion and transporting electrons, where high-n is defined by an index of refraction of at least 1.8. By fine-tuning the thicknesses (ranging from 5 nm to 40 nm) of the high-n ETL material, one can red-shift the surface plasmon frequency of the SPP modes, obtain a higher density of states (DoS) due to a flat dispersion, and optimize the charge balance in the exciton emission later (EML).

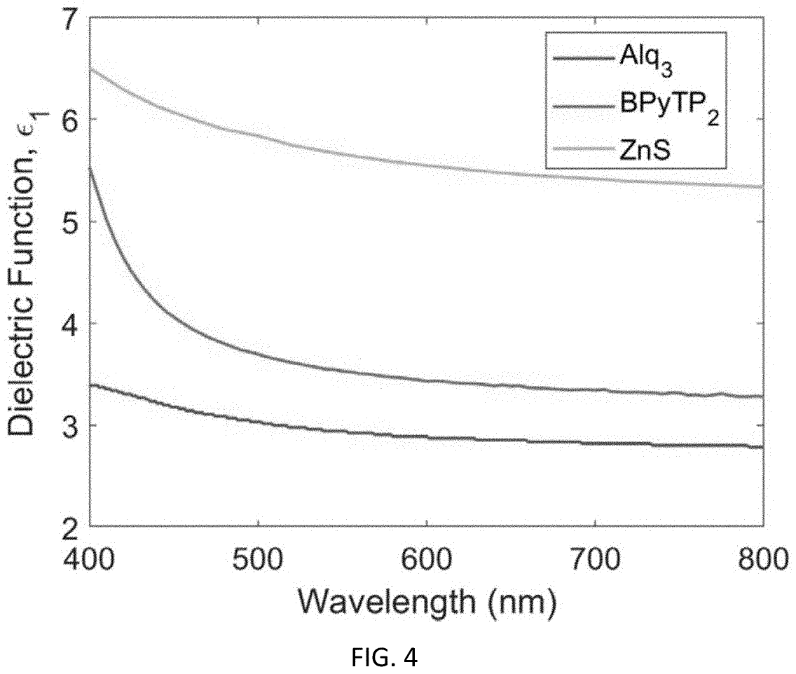

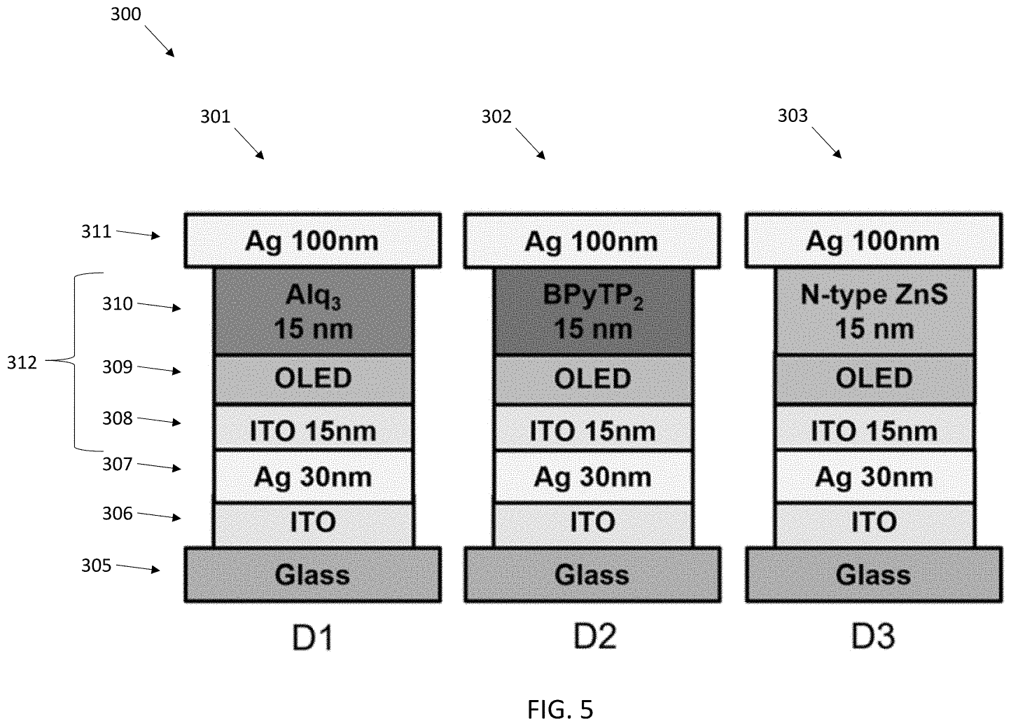

FIG. 4 shows optical constants and the simulated dispersion of three ETL candidates, Alq₃, BPyTP₂, ZnS. FIG. 5 shows exemplary OLED 300 structures for exemplary devices D1 301, D2 302 and D3 303.

With reference to FIG. 5, in some embodiments, the OLED 300 comprises a first metal electrode layer 307, an OLED stack 309 positioned over the first metal electrode layer 307, a charge transport layer 310 positioned over the OLED stack309, and a second metal electrode layer 311 positioned over the charge transport layer 310. In some embodiments, the OLED stack 309 comprises any suitable layers including but not limited to an emissive layer, an HTL, an HBL, an EML, an EBL, an interfacial layer, and in any suitable quantity and arrangement.

In some embodiments, the charge transport layer 310 is in direct contact with the second metal electrode layer 311. In some embodiments, a charge injection layer is positioned between the charge transport layer 310 and the second metal electrode layer 311. In some embodiments, the charge injection layer has a thickness of less than 20 nm, less than 10 nm, less than 5 nm, less than 2.5 nm, or any other suitable thickness. In some embodiments, the charge transport layer 310 is configured to enhance efficiency of the OLED 300. In some embodiments, the charge transport layer 310 has an index of refraction of at least 1.7. In some embodiments, the charge transport layer 310 comprises Alq₃, BPyTP₂, and/or N-type ZnS. In some embodiments, the charge transport layer 310 has a thickness between 10 nm and 30 nm, about 15 nm, or any other suitable thickness. In some embodiments, the charge transport layer 310 is configured as an electron transport layer (ETL). In some embodiments, the charge transport layer 310 is configured as a hole transport layer (HTL).

In some embodiments, the OLED 300 further comprises a substrate layer 305 positioned under the first metal electrode layer 307. In some embodiments, the substrate layer 305 comprises glass or other suitable materials, for example a material that is transparent to at least a portion of the emissive spectrum of the OLED stack309.

In some embodiments, the first metal electrode layer307 comprises an anode. In some embodiments, the first metal electrode layer 307 comprises a cathode. In some embodiments, the first metal electrode layer 307 comprises silver. In some embodiments, the first metal electrode layer 307 has a thickness of about 30 nm.

In some embodiments, the second metal electrode layer 311 comprises an anode. In some embodiments, the second metal electrode layer 311 comprises a cathode. In some embodiments, the second metal electrode layer 311 comprises silver. In some embodiments, the second metal electrode layer 311 has a thickness of about 100 nm, or at least greater than 80 nm.

In some embodiments, the second metal electrode layer 311 comprises a cathode and the charge transport layer 110 comprises an electron transport layer. In some embodiments, both the first and second metal electrode layers (307, 311) comprise silver.

In some embodiments, the OLED 300 further comprises an ITO layer 308 (top) between the first metal electrode layer 307 and the OLED stack 309. In some embodiments, the OLED 300 further comprises an ITO layer 306 (bottom) below the first metal electrode layer 307. In some embodiments, a first electrode is defined by the ITO/first metal electrode/ITO layer stack (306, 307, 308).

In some embodiments, the OLED 300 includes one or more ITO layers positioned between the charge transport layer 310 and the second metal electrode layer 311, and/or over the second metal electrode layer 311.

In some embodiments, the OLED stack 309 comprises any suitable emissive structure and thickness. In one exemplary embodiment, the structure of the OLED stack 309 can comprise 5 nm (3,3′-Di(9H-carbazol-9-yl)-1,1′-biphenyl) mCBP/30-50 nm mCBP: iridium (III) tris[3-(2,6-dimethylphenyl)-7-methylimidazo[1,2-f] phenanthridine] [Ir(dmp)3] (graded doping from 18%-8%)/10 nm dipyrazino[2,3,-f:2′,3′-h]quinoxaline 2,3,6,7,10,11-hexacarbonitrile (HATCN).

In some embodiments, the cavity 312 of OLED 300 has a Purcell factor of at least 5.

In some embodiments, the OLED 300 comprises a cavity 312 formed between first metal electrode 307 and second metal electrode layer 311, an OLED stack309 positioned within the cavity 312, and a charge transport layer 310 positioned between the OLED stack309 and the second metal electrode layer 311. In some embodiments, the charge transport layer 310 has a refractive index of at least 1.7. In some embodiments, the charge transport layer 310 has a refractive index of at least 1.9. In some embodiments, the charge transport layer 310 has a refractive index of at least 2.0.

In some embodiments, the charge transport layer 310 comprises an electron transporting material such as Alq₃, BPyTP₂, or ZnS, for example. In some embodiments, the cavity 312 has a Purcell factor of at least 5.

In some embodiments, the OLED 300 further comprises an ITO layer 308 positioned within the cavity 312. In some embodiments, the ITO layer 308 is positioned between the first metal electrode 307 and the OLED stack309. In some embodiments titanium (Ti) interfacial layers are layered between the ITO and Ag layers in the form of ITO/Ti/Ag/Ti/ITO. In some embodiments, the top ITO/Ti layer stops Ag diffusion into the organics, and the bottom Ti/ITO layer provides a wetting surface for Ag growth. In some embodiments, the thickness range of the top ITO layer 308, first metal electrode layer 307, and bottom ITO layer 306 is 15-30 nm, 16-30 nm, and 20-100 nm, respectively. In some embodiments, the Ti interfacial layers between 307/308, and 306/307 are each 2-3 nm thick. In some embodiments, the OLED stack 309 is a white OLED stack.

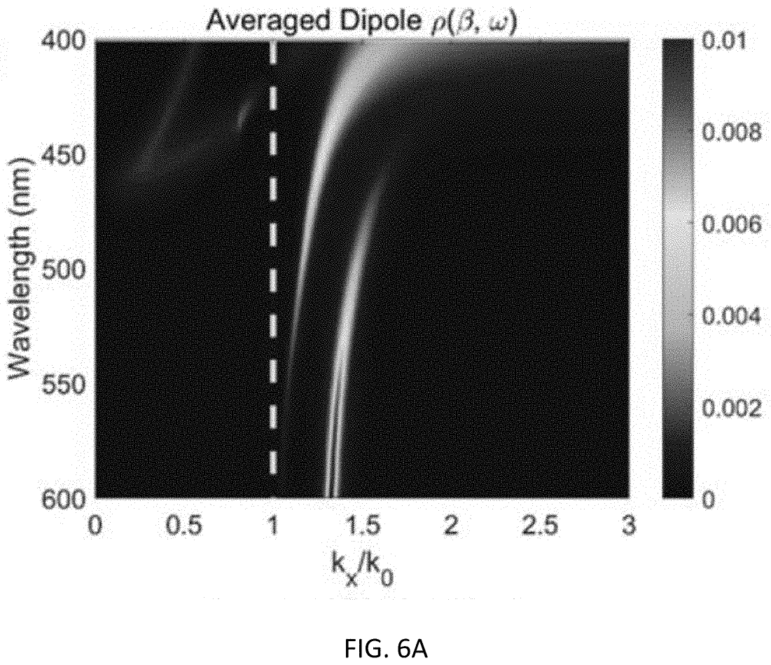

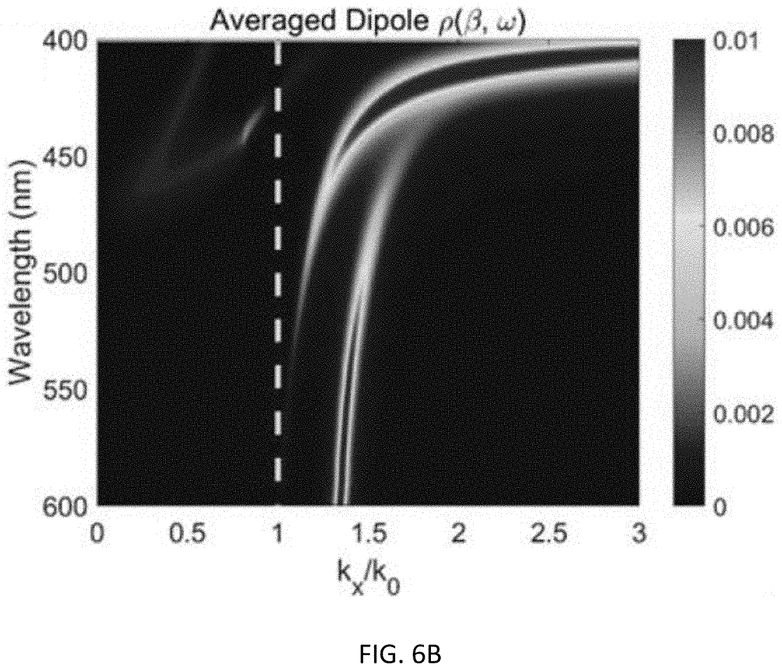

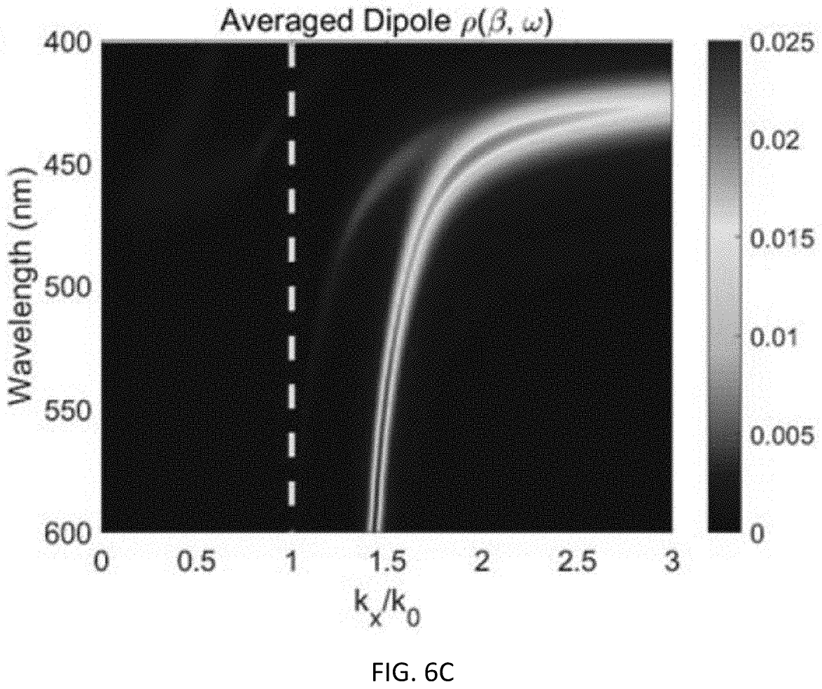

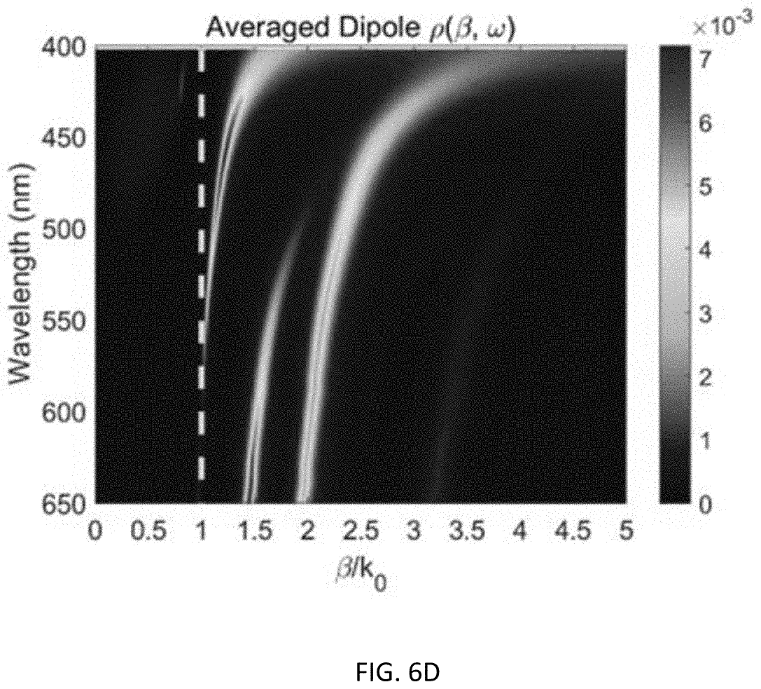

FIGS. 6A-6D describe the radiative power dissipated at each wavelength and propagation wavevector. The color plot indicates the density of states of the dissipation channel. The total radiation power, or the normalized Purcell factor, is then described as:

F_{P}(ω)∝∫₀^{∞}μ(ω)×ρ(kₓ,ω)dkₓ (3)

where μ is the transition dipole moment. In the region kₓ<1, the radiative power is outcoupled or trapped in the waveguided mode in the device planar structure, while in the region kₓ>1, the radiative power is mainly coupled to the SPP modes of the Ag/charge transport layer surface, and the asymptote surface plasma frequency of the three devices follows: D3(ZnS) 103<D2(BPyPT₂) 102<D1(Alq₃) 101. Here the impact of surface roughness is neglected. For exciton emission in the blue region, for example, peaked at 470 nm, a more redshifted SPP dispersion means that there is more radiative power coupled to the flat curve of density of states (DoS). Combined with previous methods, by coupling to multiple SPP modes at different Ag surfaces as in FIG. 6D, this method provides another degree of freedom for enhancing the Purcell effect.

However, the balance between the Purcell effect and the EQE of an OLED device must be considered for optimizing the device lifetime. For a commercialized blue phosphor with internal quantum efficiency of around 50%, and exciton emission peak at 466 nm, one can define the figure of merit of a long-lived blue phosphorescent device as:

$$Figure of Merit = \frac{{F}_{p} {η}_{e x t}}{{η}_{e xt , 0}} = [ {F}_{p} \times PLQY + ( 1 - PLQY ) ] {η}_{o u t} \qquad ( 4 )$$

where the figure of merit of a conventional device with Al/LiQ/Organics/ITO structure usually ranges from 1 to 1.5, while the disclosed optimized OLED design 100 is peaked at around 9 to 10.

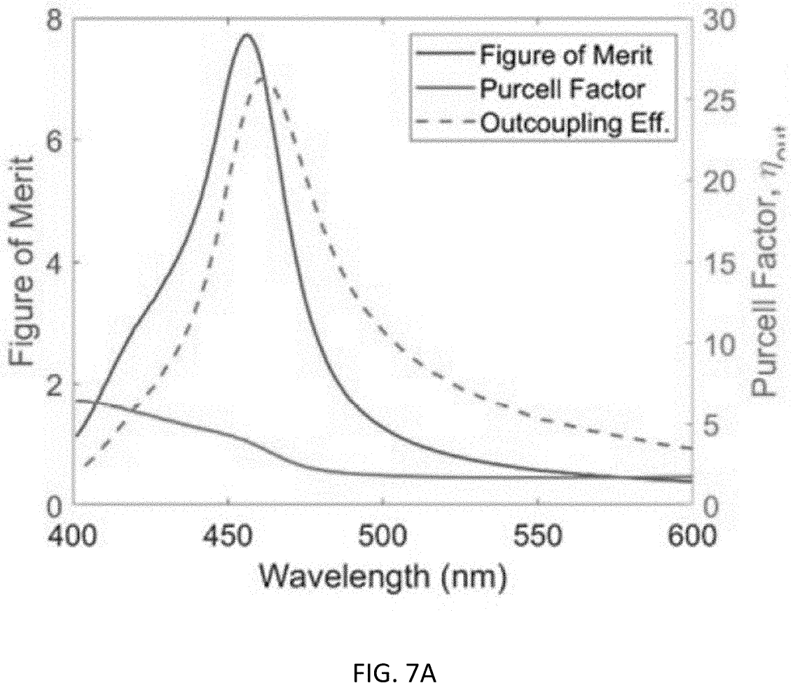

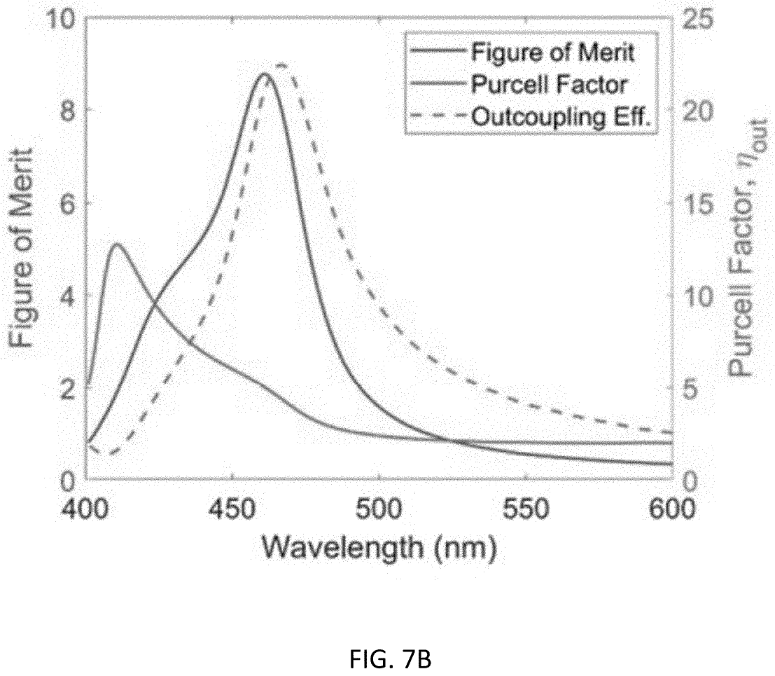

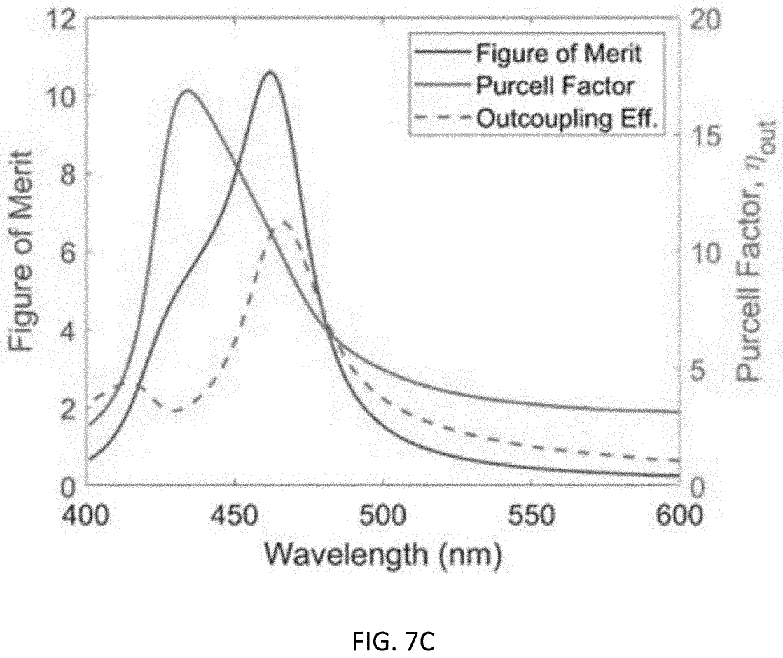

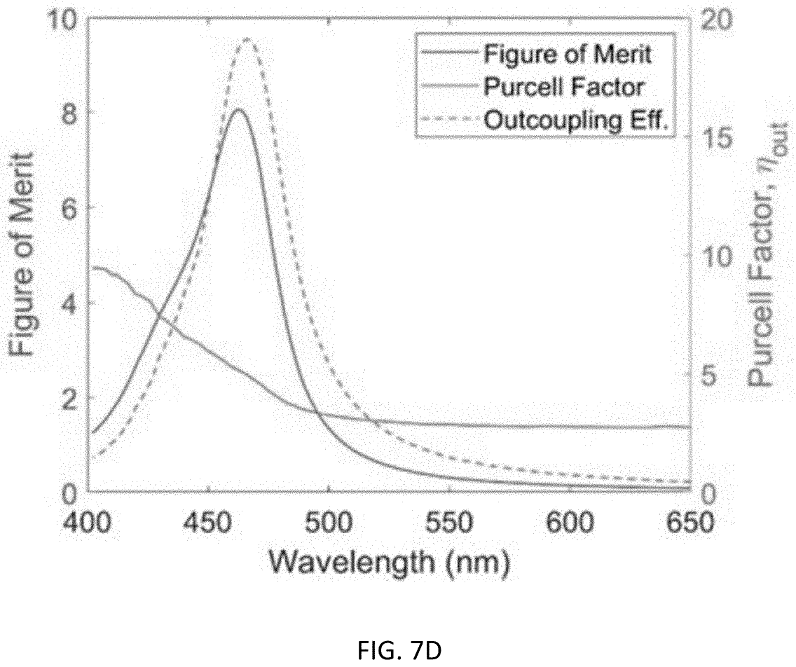

From the simulation results in FIGS. 7A-7D, the optimized SPP coupling is between the scenario of D2 102 and D3 103, in which the Purcell effect is prominent without losing too much outcoupling efficiency. This also indicates the SPP modes should be detuned from the outcoupling peak frequency.

### Fabrication and Characterization:

In some embodiments, cavity OLED devices are deposited using vapor thermal evaporation (VTE) in high vacuum. Thin Ag layers are doped with Cu, Al or wetted by sputtering thin Ti or NiCr. ITO is deposited by sputtering.

External quantum efficiency (EQE) and J-V curve is measured by a parameter analyzer with precision down to fA. Exciton lifetime is measured via transient photoluminescence using a chirped pulse amplifier (CPA) laser, an optical parametric amplifier (OPA) and a streak camera/single photon counter. Device lifetime and voltage rise is measured using Si photodiodes under continuous, steady current supply.

Combination with Other Materials

The materials described herein as useful for a particular layer in an organic light emitting device may be used in combination with a wide variety of other materials present in the device. For example, emissive dopants disclosed herein may be used in conjunction with a wide variety of hosts, transport layers, blocking layers, injection layers, electrodes and other layers that may be present. The materials described or referred to below are non-limiting examples of materials that may be useful in combination with the compounds disclosed herein, and one of skill in the art can readily consult the literature to identify other materials that may be useful in combination.

Various materials may be used for the various emissive and non-emissive layers and arrangements disclosed herein. Examples of suitable materials are disclosed in U.S. Patent Application Publication No. 2017/0229663, which is incorporated by reference in its entirety.

### Conductivity Dopants

A charge transport layer can be doped with conductivity dopants to substantially alter its density of charge carriers, which will in turn alter its conductivity. The conductivity is increased by generating charge carriers in the matrix material, and depending on the type of dopant, a change in the Fermi level of the semiconductor may also be achieved. Hole-transporting layer can be doped by p-type conductivity dopants and n-type conductivity dopants are used in the electron-transporting layer.

### HIL/HTL

A hole injecting/transporting material to be used in the present disclosure is not particularly limited, and any compound may be used as long as the compound is typically used as a hole injecting/transporting material.

### EBL

An electron blocking layer (EBL) may be used to reduce the number of electrons and/or excitons that leave the emissive layer. The presence of such a blocking layer in a device may result in substantially higher efficiencies, and/or longer lifetime, as compared to a similar device lacking a blocking layer. Also, a blocking layer may be used to confine emission to a desired region of an OLED. In some embodiments, the EBL material has a higher LUMO (closer to the vacuum level) and/or higher triplet energy than the emitter closest to the EBL interface. In some embodiments, the EBL material has a higher LUMO (closer to the vacuum level) and or higher triplet energy than one or more of the hosts closest to the EBL interface. In one aspect, the compound used in EBL contains the same molecule or the same functional groups used as one of the hosts described below.

### Host

The light emitting layer of the organic EL device of the present disclosure preferably contains at least a metal complex as light emitting material, and may contain a host material using the metal complex as a dopant material. Examples of the host material are not particularly limited, and any metal complexes or organic compounds may be used as long as the triplet energy of the host is larger than that of the dopant. Any host material may be used with any dopant so long as the triplet criteria is satisfied.

### HBL

A hole blocking layer (HBL) may be used to reduce the number of holes and/or excitons that leave the emissive layer. The presence of such a blocking layer in a device may result in substantially higher efficiencies and/or longer lifetime as compared to a similar device lacking a blocking layer. Also, a blocking layer may be used to confine emission to a desired region of an OLED. In some embodiments, the HBL material has a lower HOMO (further from the vacuum level) and or higher triplet energy than the emitter closest to the HBL interface. In some embodiments, the HBL material has a lower HOMO (further from the vacuum level) and or higher triplet energy than one or more of the hosts closest to the HBL interface.

### ETL

An electron transport layer (ETL) may include a material capable of transporting electrons. The electron transport layer may be intrinsic (undoped), or doped. Doping may be used to enhance conductivity. Examples of the ETL material are not particularly limited, and any metal complexes or organic compounds may be used as long as they are typically used to transport electrons.

### Charge Generation Layer (CGL)

The CGL plays an essential role in the performance, which is composed of an n-doped layer and a p-doped layer for injection of electrons and holes, respectively. Electrons and holes are supplied from the CGL and electrodes. The consumed electrons and holes in the CGL are refilled by the electrons and holes injected from the cathode and anode, respectively; then, the bipolar currents reach a steady state gradually. Typical CGL materials include n and p conductivity dopants used in the transport layers.

As previously disclosed, OLEDs and other similar devices may be fabricated using a variety of techniques and devices. For example, in OVJP and similar techniques, one or more jets of material is directed at a substrate to form the various layers of the OLED.

The disclosures of each and every patent, patent application, and publication cited herein are hereby incorporated herein by reference in their entirety. While this invention has been disclosed with reference to specific embodiments, it is apparent that other embodiments and variations of this invention may be devised by others skilled in the art without departing from the true spirit and scope of the invention.

What is claimed is:

1. An organic light emitting device, comprising:
a first electrode;
an emissive layer positioned over the first electrode;
a charge transport layer positioned over the emissive layer; and
a second electrode positioned over the charge transport layer;
wherein the charge transport layer is in direct contact with the second electrode, and wherein the charge transport layer has an index of refraction of at least 1.7.

2. The organic light emitting device of claim 1, wherein the charge transport layer comprises a material selected from Alq₃, BPyTP₂, or ZnS.

3. The organic light emitting device of claim 1, wherein the charge transport layer has a thickness of between 10 nm and 30 nm.

4. The organic light emitting device of claim 1, wherein the charge transport layer has a thickness of about 15 nm.

5. The organic light emitting device of claim 1, wherein the second electrode is a cathode and the charge transport layer is an electron transport layer.

6. The organic light emitting device of claim 1, wherein the first electrode and the second electrode both comprise silver.

7. The organic light emitting device of claim 1, wherein the first electrode has a thickness of about 30 nm, and the second electrode has a thickness of about 100 nm.

8. The organic light emitting device of claim 1, further comprising a first ITO layer between the first electrode and the emissive layer.

9. The organic light emitting device of claim 8, wherein the first ITO layer has a thickness of about 15 nm.

10. The organic light emitting device of claim 8, further comprising a second ITO layer below the first electrode.

11. The organic light emitting device of claim 1, wherein the charge transport layer has a refractive index of at least 1.9.

12. The organic light emitting device of claim 1, wherein the charge transport layer has a refractive index of at least 2.0.

13. An organic light emitting device, comprising:
a cavity formed between first and second metal electrodes;
an organic light emitting element positioned within the cavity; and
an efficiency enhancement layer positioned between the organic light emitting element and the second silver electrode, the efficiency enhancement layer having a refractive index of at least 1.7.

14. The organic light emitting device of claim 13, wherein the efficiency enhancement layer has a refractive index of at least 1.9.

15. The organic light emitting device of claim 13, wherein the efficiency enhancement layer has a refractive index of at least 2.0.

16. The organic light emitting device of claim 13, wherein the efficiency enhancement layer comprises an electron transporting material.

17. The organic light emitting device of claim 13, wherein the cavity has a Purcell factor of at least 5.

18. The organic light emitting device of claim 13, further comprising an ITO layer positioned within the cavity.

19. The organic light emitting device of claim 18, wherein the ITO layer is positioned between the first metal electrode and the organic light emitting element.

20. The organic light emitting element of claim 13, wherein the organic light emitting element is a white organic light emitting element.
